(19) United States
(12) Patent Application Publication
(10) Pub. No.: US 2025/0309136 A1
(43) Pub. Date: Oct. 2, 2025

(54) SHIELDED CONDUCTIVE DEVICE, A METHOD FOR FORMING THE SAME AND AN ELECTRONIC PACKAGE ASSEMBLY

(71) Applicant: JCET STATS ChipPAC Korea Limited, Incheon (KR)

(72) Inventors: HyeonChul LEE, Seoul (KR); KyoungHee PARK, Seoul (KR); KyungHwan KIM, Seoul (KR); JiYeon LEE, Incheon (KR); HyeWon LEE, Incheon (KR); DongGyu LEE, Seoul (KR)

(21) Appl. No.: 19/096,756

(22) Filed: Apr. 1, 2025

(30) Foreign Application Priority Data
Apr. 2, 2024 (CN) 202410395956.X

(51) Int. Cl. H01L 23/552; H01L 21/48; H01L 21/56; H01L 21/683; H01L 21/78; H01L 23/00; H01L 23/498; H01L 23/538; H01L 25/16; H10D 80/30

(52) U.S. Cl. CPC H01L 23/552; H01L 21/4853; H01L 21/568; H01L 21/6836; H01L 21/78; H01L 23/49811; H01L 23/5385; H01L 25/16; H10D 80/30; H01L 24/16; H01L 24/96; H01L 24/97; H01L 2224/16225; H01L 2224/96; H01L 2224/97; H01L 2924/19105

(57) ABSTRACT

A shielded conductive device, a method for forming the same and an electronic package assembly is provided. The shielded conductive device comprises: a dielectric base having a top surface and a bottom surface, and a lateral surface extending between the top surface and the bottom surface; top conductive pads and bottom conductive pads formed on the top surface and the bottom surface of the dielectric base, respectively; a plurality of conductive pillars extending through the dielectric base and electrically connecting the top conductive pads with the bottom conductive pads, wherein the plurality of conductive pillars comprise at least one reference conductive pillar and at least one signal conductive pillar; and a shielding layer formed on the lateral surface of the dielectric base, and wherein the shielding layer is electrically connected to the at least one reference conductive pillar through at least a corresponding top conductive pad or bottom pad.

### TECHNICAL FIELD

The present application generally relates to semiconductor technology, and more particularly, to a shielded conductive device, a method for forming the same and an electronic package assembly.

### BACKGROUND OF THE INVENTION

In recent years, wireless communication modules are widely used in electronic devices such as cellular telephones, wireless networking devices and headsets. Wireless communication modules use electromagnetic waves (microwaves or radio waves), magnetic fields, and electric fields to enable wireless communication between devices. Typically, the wireless communication modules are packed into devices with various electronic modules for more functionalities. The wireless communication modules may be electrically connected with other modules in the device through conductive structures such as e-bars. However, when signals emitted from the wireless communication modules are transmitted through the e-bars, electromagnetic interference induced by the signals may disturb other electronic modules, especially those electronic modules disposed adjacent to the e-bars, which may adversely affect the performance of these electronic modules.

Therefore, a need exists for a conductive device with better electromagnetic interference shielding in an electronic package.

### SUMMARY OF THE INVENTION

An objective of the present application is to provide a shielded conductive device with better electromagnetic interference shielding and a method for forming the same.

According to an aspect of the present application, a shielded conductive device is provided. The shielded conductive device comprises: a dielectric base having a top surface and a bottom surface, and a lateral surface extending between the top surface and the bottom conductive surface; top conductive pads and bottom conductive pads formed on the top surface and the bottom surface of the dielectric base, respectively; a plurality of conductive pillars extending through the dielectric base and electrically connecting the top conductive pads with the bottom conductive pads, wherein the plurality of conductive pillars comprise at least one reference conductive pillar configured for connection with a reference voltage and at least one signal conductive pillar configured for signal transmission; and a shielding layer formed on the lateral surface of the dielectric base to reduce electromagnetic interferences propagating into an external space of the shielded conductive device, and wherein the shielding layer is electrically connected to the at least one reference conductive pillar through at least a corresponding top conductive pad or bottom conductive pad.

According to another aspect of the present application, a method for forming shielded conductive devices is provided. The method comprises: providing a substrate strip comprising a plurality of conductive devices, wherein each of the plurality of conductive devices comprises: a dielectric base having a top surface and a bottom surface and a lateral surface extending between the top surface and the bottom surface; top conductive pads and bottom conductive pads formed on the top surface and the bottom surface of the dielectric base, respectively; and a plurality of conductive pillars extending through the dielectric base and electrically connecting the top conductive pads with the bottom conductive pads, wherein the plurality of conductive pillars comprise at least one reference conductive pillar configured for connection with a reference voltage and at least one signal conductive pillar configured for signal transmission; attaching a cover tape onto a top surface of the substrate strip; singulating the substrate strip to separate the plurality of conductive devices from each other; loading the plurality of conductive devices onto a carrier platform with the bottom surfaces of the dielectric bases of the conductive devices attached on the carrier platform; depositing towards the conductive devices a shielding material to form a shielding layer on a lateral surface of the dielectric base of each of the conductive devices, wherein the shielding layer is electrically connected to the at least one reference conductive pillar through at least a corresponding top conductive pad or bottom conductive pad; and removing the cover tape and the carrier platform from the plurality of conductive devices.

According to another aspect of the present application, an electronic package assembly is provided. The electronic package assembly comprises: a base substrate and an upper substrate; at least one electronic component mounted on a front surface of the base substrate; at least one shielded conductive device mounted on the front surface of the base substrate and between the base substrate and the upper substrate, and for electrically connecting the base substrate and the upper substrate, wherein the shielded conductive device comprises: a dielectric base having a top surface and a bottom surface and a lateral surface extending between the top surface and the bottom surface; top conductive pads and bottom conductive pads formed on the top surface and the bottom surface of the dielectric base, respectively; a plurality of conductive pillars extending through the dielectric base and electrically connecting the top conductive pads with the bottom conductive pads, wherein the plurality of conductive pillars comprise at least one reference conductive pillar configured for connection with a reference voltage and at least one signal conductive pillar configured for signal transmission; and a shielding layer formed on the lateral surface of the dielectric base to reduce electromagnetic interferences propagating into an external space of the shielded conductive device, and wherein the shielding layer is electrically connected to the at least one reference conductive pillar through at least a corresponding top conductive pad or bottom conductive pad, wherein the bottom conductive pads of the at least one shielded conductive device are attached on the front surface of the base substrate via solder bumps; and at least one upper electronic component mounted on the upper substrate and electrically connected with the at least one shielded conductive device, wherein the upper electronic component comprises a wireless communication device.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates an electronic package assembly according to a first embodiment of the present application.

FIGS. 1B and 1C illustrate a shielded conductive device shown in FIG. 1A.

FIGS. 2A to 2G illustrate various steps of a method for forming a shielded conductive device according to a second embodiment of the present application.

FIGS. 3A to 3D illustrate various steps of a method for forming an electronic package assembly according to a third embodiment of the present application.

FIGS. 4A to 4C illustrate various steps of a method for forming an electronic package assembly according to a fourth embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, wireless communication modules are packed into devices with various electronic modules for more functionalities. Typically, in an electronic package assembly with multi-layer structures, wireless communication modules on one layer may be electrically connected with electronic modules on other layers through connection structures such as e-bars. When the wireless communication modules are in operation, the signals emitted from the wireless communication modules are transmitted through the e-bars. However, electromagnetic interference induced by the signals in e-bars may propagate into an external space, which may disturb other electronic modules, especially those electronic modules disposed adjacent to the e-bars, which may adversely affect the performance of these electronic modules.

To address this issue, a conductive device with a shielding layer on its lateral surface is provided. The shielded conductive device includes at least one reference conductive pillar configured for connection with a reference voltage and at least one signal conductive pillar configured for signal transmission, where the shielding layer is electrically connected to the at least one reference conductive pillar to block electromagnetic interference induced by the signals transmitted through the at least one signal conductive pillar. In some embodiments, the shielded conductive device can be used in an electronic package assembly which incorporates devices emitting or receiving electromagnetic waves and inducing electromagnetic interference, such as a WiFi communication device or a Bluetooth communication device.

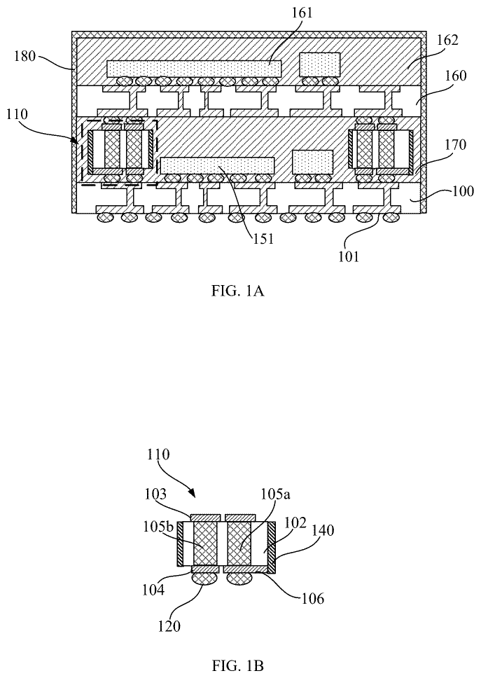

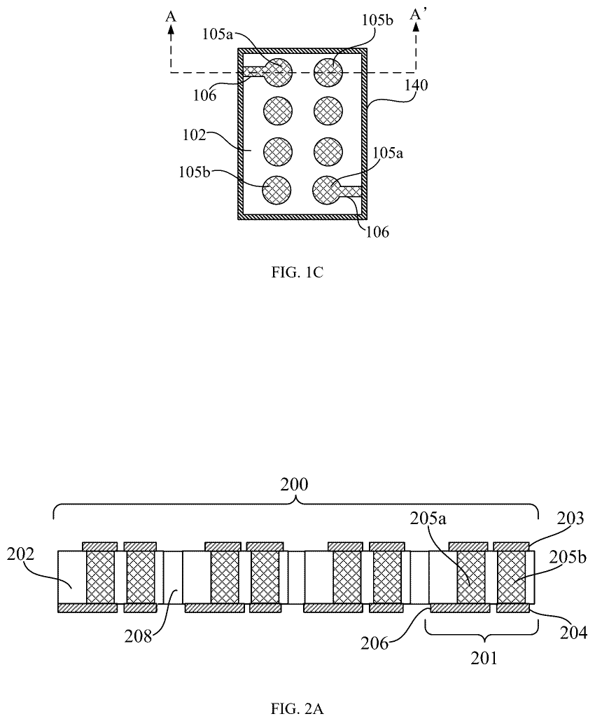

FIG. 1A illustrates an electronic package assembly according to a first embodiment of the present application. FIGS. 1B and 1C illustrate a shielded conductive device shown in FIG. 1A. It can be appreciated that similar shielded conductive devices can be used in the electronic package assembly shown in FIG. 1A, depending on the needs of a circuit in the assembly.

As shown in FIG. 1A, the electronic package assembly has a multi-layer structure, i.e., multiple layers of electronic components are incorporated in the assembly to provide for a compact structure. The electronic package assembly includes a base substrate 100 with embedded interconnect wires 101. The base substrate 100 includes a front surface and a back surface, which are opposite to each other. The front surface of the base substrate 100 may serve as a platform where electronic component(s) and conductive devices can be mounted on. That is, the base substrate 100 serves as a platform at a lower layer of the multi-layers structure of the electronic package assembly. In some embodiments, the electronic package assembly may be a double-sided mounted (DSM) package, and accordingly, the back surface may also serve as another platform where electronic component(s) may be mounted. Multiple sets of conductive pads (not shown) can be formed on the front surface and/or back surface of the base substrate 100 for the mounting of the electronic components and the conductive devices. It can be appreciated that the multiple sets of conductive pads may be exposed portions of interconnect wires 101 formed within the base substrate 100.

The electronic package assembly further includes at least one electronic component 151 mounted on a front surface of the base substrate 100 via, for example, solder bumps. In some embodiments, the electronic component 151 may include an ultra-wide bandwidth (UWB) communication integrated circuit chip. The UWB communication integrated circuit chip may be sensitive to electromagnetic interference when in an operation state. In some other embodiments, the electronic component may also include a high accuracy sensor, a semiconductor chip, a resistor or a capacitor which should also be protected from electromagnetic interference when in operation.

As shown in FIG. 1A, the electronic package assembly further includes an upper substrate 160 with embedded interconnect wires and at least one shielded conductive device 110. The upper substrate 160 includes a front surface and a back surface, which are opposite to each other. The front surface of the upper substrate 160 may also serve as a platform where electronic component(s) can be mounted on. That is, the upper substrate 160 serves as a platform at an upper layer of the multi-layers structure of the electronic package assembly. It can be appreciated additional layers of substrates may be integrated within the assembly if desired.

The at least one shielded conductive device 110 is mounted on the front surface of the base substrate 100 and between the base substrate 100 and the upper substrate 160, which electrically connects the base substrate 100 and the upper substrate 160. In particular, as shown in FIGS. 1B and 1C, the shielded conductive device 110 includes a dielectric base 102, a plurality of conductive pillars extending through the dielectric base 102 and a shielding layer 140 formed on the lateral surface of the dielectric base 102. In other words, the conductive pillars provide various signal/power paths in the assembly which extend generally vertically between adjacent layers of substrate. In some embodiments, the shielded conductive device 110 may be mounted onto the base substrate 100 and the upper substrate 160 via solder bumps or using similar surface mounting techniques.

Furthermore, the electronic package assembly includes at least one upper electronic component 161 mounted on the upper substrate 160 via, for example, solder bumps. The upper electronic component 161 is electrically connected with the at least one shielded conductive device 110 through the solder bumps and interconnect wires within the upper substrate 160. In other words, the upper electronic component 161 is electrically connected with the base substrate 100, and then connected with other electronic modules through the at least one shielded conductive device 110. In some embodiments, the upper electronic component 161 includes a wireless communication device which requires electromagnetic communication with the external space to emit and receiving wireless signals, such as a WiFi communication device or a Bluetooth communication device. The wireless communication device emits and transmits signals in forms of electromagnetic waves. In the embodiment shown in FIG. 1A, when the wireless communication device is in operation, the signals from the wireless communication modules are transmitted to other electronic modules through the interconnect wires within the upper substrate 160 and the conductive pillars within the at least one shielded conductive device 110 for required functionality. With the shielding layer 140, electromagnetic interferences induced by the signals in the conductive pillars of the shielded conductive device 110 may be prevented from propagating outside of the shielded conductive device 110 and from disturbing the electronic component(s) 151, thereby enhancing performance of the electronic component(s) 151 disposed around the shielded conductive device 110, especially for those electronic component(s) 151 which are adjacent to the shielded conductive device 110. In some embodiments, it can be appreciated that more than one shielded conductive device 110 may be mounted onto the front surface of the base substrate 100 to provide sufficient coupling between the at least one upper electronic component 161 and other electronic components.

In some other embodiments, the electronic package assembly also includes at least one additional upper electronic component mounted on the front surface of the upper substrate 160. The additional upper electronic component may not actively transmit electromagnetic wave signals, which may include a semiconductor chip, a resistor or a capacitor, for example. Furthermore, the electronic package assembly may include at least one additional conductive device mounted on the front surface of the base substrate 100, which is used for electrical connection between the at least one additional upper electronic component and other electronic modules within the package assembly. In particular, the additional conductive device may have similar structure as the shielded conductive device 110 except that the additional conductive device may not include the shielding layer 140 since the electromagnetic interference induced by the additional conductive device may be at a relatively low level.

Still referring to FIG. 1A, the electronic package assembly further includes a molding layer 170 between the front surface of the base substrate 100 and the bottom surface of the upper substrate 160, which encapsulates the at least one electronic component 151 and the at least one shielded conductive device 110. An upper molding layer 162 is formed on the front surface of the upper substrate 160, which encapsulates the upper electronic component 161. Furthermore, an additional shielding layer 180 is disposed on lateral surfaces of the base substrate 100, the molding layer 170, the upper substrate 160, the upper molding layer 162 and a top surface of the upper molding layer 162 to protect other parts of the electronic package assembly from electromagnetic interferences.

In the embodiment shown in FIG. 1A, since the shielding layer 140 of the shielded conductive device 110 may work independently with the additional shielding layer 180 on the outer surface of the electronic package assembly, the shielded conductive device 110 may be disposed at any position in the electronic package assembly, e.g., at the center of the base substrate 100, not only limited to adjacency of the additional shielding layer 180.

The electronic package assembly further includes solder bumps formed on the back surface of the base substrate 100 for mounting of the electronic package assembly onto external electronic modules.

In the following, the shielded conductive device 110 will be described with reference to FIGS. 1B and 1C in more details. In particular, FIG. 1B illustrates a cross-sectional view of the shielded conductive device 110 shown in FIG. 1A along line AA′ in FIG. 1C, and FIG. 1C illustrates a bottom view of the shielded conductive device 110 shown in FIG. 1A.

As shown in FIG. 1B, the shielded conductive device 110 includes a dielectric base 102. The material of the dielectric base 102 may be a dielectric material such as silicon dioxide or a semiconductor material such as silicon. The dielectric base 102 includes a top surface and a bottom surface, and a lateral surface extending between the top surface and the bottom surface. Within the dielectric base 102, a plurality of conductive pillars extend from the top surface to the bottom surface of the dielectric base 102. The plurality of conductive pillars include at least one reference conductive pillar 105a and at least one signal conductive pillar 105b. The reference conductive pillar 105a can be connected with a reference voltage, e.g., to a ground node/line. The signal conductive pillar 105b may serve as an electrical connection or a signal transmitting channel between electronic components on the upper substrate 160 and the base substrate 100, for example, between the wireless communication device 161 and the electronic component on the base substrate 100 shown in FIG. 1A. Furthermore, the shielded conductive device 110 includes a shielding layer 140 on the lateral surface of the dielectric base 102, and the shielding layer 140 is electrically connected to the at least one reference conductive pillar at a reference voltage such as being grounded, thereby blocking electromagnetic interference from propagating into an external space of the shielded conductive device 110. In particular, materials used for the shielding layer 140 may include carbons, ceramics, cement, metals, conducting polymers, etc.

FIG. 1C shows a layout pattern of the reference conductive pillars 105a and the signal conductive pillars 105b. For simplicity, the top and bottom conductive pads are omitted in FIG. 1C. As shown in FIG. 1C, the reference conductive pillars 105a and the signal conductive pillars 105b may have the same size, which may be formed of the same material and be formed simultaneously using the same fabrication process. The dielectric base 102 may be a cuboid layout, which includes four peripheries together forming the lateral surface of the dielectric base 102. In the embodiment shown in FIG. 1C, the shielded conductive device 110 includes two reference conductive pillars 105a each disposed at a corner of the dielectric base 102, which is adjacent to two peripheries of the dielectric base 102. In this way, it may be more convenient to connect the reference conductive pillars 105a with the shielding layer 140 to provide a reference voltage. In some other embodiments, the number of the reference conductive pillars 105a may be one, two, or even more. Preferably, the conductive pillar(s) may be disposed adjacent to at least one of the peripheries of the dielectric base 102. In these embodiments, any of the conductive pillars may be chosen to be a reference conductive pillar 105a as long as the conductive pillar can be connected with the shielding layer 140 and the reference voltage, where the number and positions of the reference conductive pillars 105a may be more flexible.

Moreover, the shielded conductive device 110 further includes top conductive pads 103 formed on the top surface of the dielectric base 102 and bottom conductive pads 104 formed on the bottom surface of the dielectric base 102 for mounting of the electronic components. The conductive pillars electrically connect the top conductive pads 103 and the bottom conductive pads 104. It can be appreciated that the top conductive pads 103 and bottom conductive pads 104 may be exposed portions of respective conductive pillars. For the reference conductive pillars 105a shown in FIGS. 1B and 1C, there are conductive patterns 106 formed on the bottom surface of the dielectric base 102, where the conductive patterns 106 are disposed between the shielding layer 140 and corresponding bottom conductive pad(s) 104 on reference conductive pillar(s) 105a, thereby connecting the reference conductive pillar(s) 105a with the shielding layer 140. In some other embodiments, conductive patterns 106 are formed on the top surface of the dielectric base 102, and between the shielding layer 140 and corresponding top conductive pad(s) on the reference conductive pillar(s) 105a. In some alternative embodiments, conductive patterns 106 may be formed on both of the top surface and the bottom surface of the dielectric base 102. Since the conductive patterns 106 are formed on the surfaces of the dielectric base 102, a fabrication process of the conductive patterns 106 may be simple and low-cost without affecting the reference conductive pillar(s) 105a. In other words, even if the layouts of the reference conductive pillar(s) 105a and the signal conductive pillar(s) 105b may vary among different shielded conductive devices 110, the dielectric base 102, the conductive pillars extending within the dielectric base 102 and the top and bottom conductive pads 103, 104 of each of the shielded conductive devices 110 can have similar structures, which enables mass production for higher efficiency and lower cost.

Furthermore, the shielding layer 140 on the lateral surface of the dielectric base 102 does not extend to either of the top surface and the bottom surface of the dielectric base 102. In this way, the shielding layer 140 may not be connected with either of the respective top conductive pad(s) 103 or bottom conductive pad(s) 104 on the signal conductive pillar(s) 105b, which avoids short circuit risks and prevents the electromagnetic interference from leaking out of the shielded conductive devices 110. In particular, a portion of the shielding layer 140 which is in direct contact with the conductive patterns 106 has a larger height than that of the shielding layer 140 on other parts of the lateral surface of the dielectric base 102.

Still referring to FIGS. 1B and 1C, the shielded conductive device 110 further includes solder bumps 120 formed on at least a portion of the top and bottom conductive pads 104 for mounting of the shielded conductive device 110 onto external electronic modules.

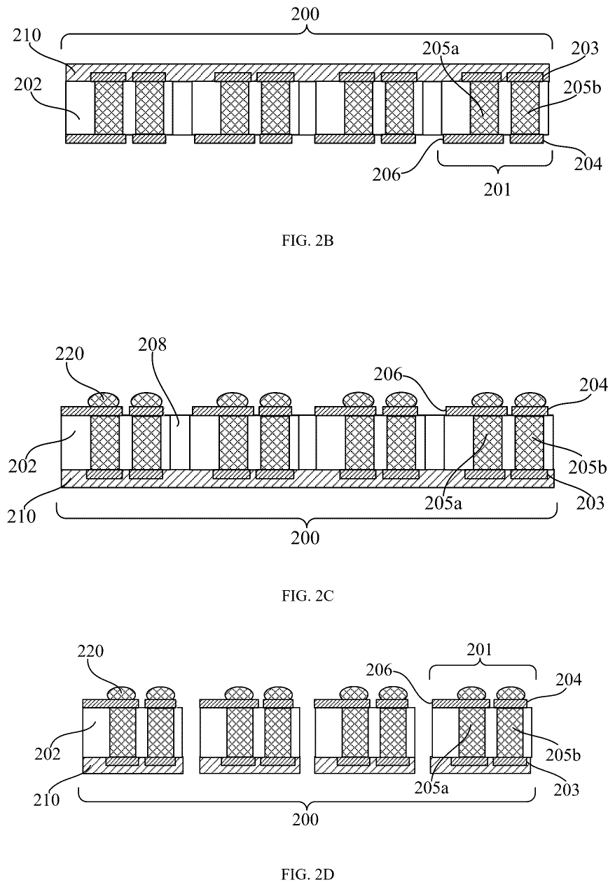

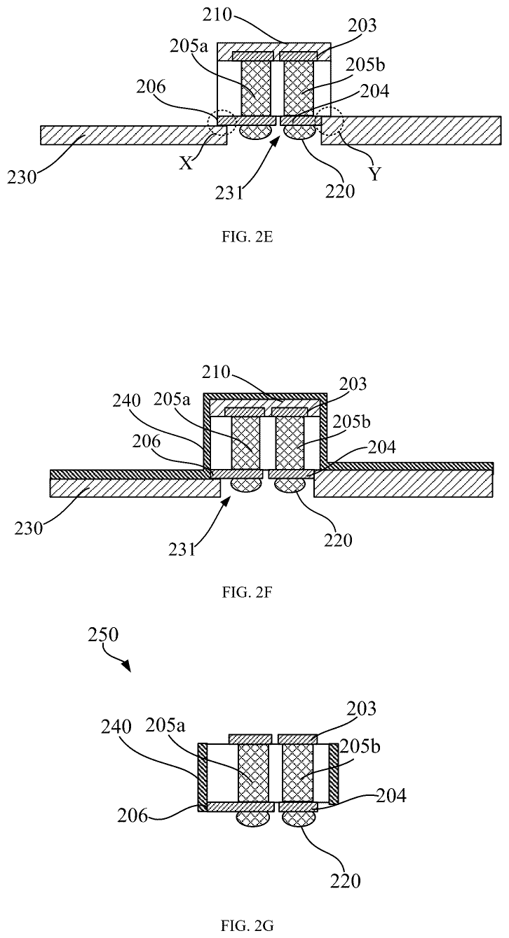

FIGS. 2A to 2G illustrate various steps of a method for forming a shielded conductive device according to a second embodiment of the present application. The shielded conductive device may have a similar structure as the shielded conductive device 110 illustrated in FIGS. 1A to 1C.

As shown in FIG. 2A, a substrate strip 200 including a plurality of non-singulated conductive devices 201 is provided. Each of the conductive devices 201 includes a dielectric base 202, a plurality of conductive pillars (including reference conductive pillar(s) 205a and signal conductive pillar(s) 205b), top conductive pads 203, bottom conductive pads 204, and conductive patterns 206 connected to the reference conductive pillar(s) 205a and extending to a lateral surface of the dielectric base 202. The detailed structures of the above-mentioned components may be similar to those of the shielded conductive device 110 illustrated in FIGS. 1A to 1C, which will not be elaborated in detail here for simplicity. In this embodiment, the substrate strip 200 may also include a plurality of linkage portions 208 similar as saw streets, each of which is positioned between two dielectric bases 202 of adjacent conductive devices, thus connecting the plurality of conductive devices 201 as the substrate strip 200. Also, it can be appreciated that in some embodiments, both the linkage portions 208 and the dielectric bases 202 are originally formed together and are not required to be assembled together as the substrate strip 200.

In this embodiment, each of the conductive devices 201 may have the same or similar structure, where the number and position of the reference conductive pillar(s) 205a and the number and position of the signal conductive pillar(s) 205b may be the same. In some other embodiments, the number and position of the reference conductive pillar(s) 205a or/and the number and position of the signal conductive pillar(s) 205b of the conductive devices may be different among different conductive devices 201. During a fabrication process, the conductive pillars of each of the conductive devices 201 may be formed simultaneously and similarly within the dielectric bases 202, and a subsequent formation of the conductive patterns 206 may have different layouts among different conductive devices 201, which allows for various layouts of the reference conductive pillar(s) 205a or/and the signal conductive pillar(s) 205b of the conductive devices 201.

Next, a cover tape 210 is attached onto a top surface of the substrate strip 200. As shown in FIG. 2B, the cover tape 210 covers the top conductive pads 203 and top surface of the dielectric bases 202, which prevents subsequent formation of a shielding layer 240 onto the top conductive pads 203 and top surfaces of the dielectric bases 202, avoiding short circuit risks when the conductive devices are used in circuits. The cover tape 210 should provide sufficient protection for top conductive pads 203 and top surfaces of the dielectric bases 202 and at the same time, be easy to get removed with undesired residuals. In some embodiments, the cover tape 210 may be an ultraviolet (UV) sensitive tape, which may be hardened after irradiation by UV light with a certain wavelength range. In some other embodiments, the cover tape 210 may include adhesive materials such as adhesive polymer, plastic, ceramics or the like. Next, as shown in FIG. 2C, solder bumps 220 are formed onto the bottom conductive pads 204 of the conductive devices 201 for mounting of the conductive devices onto external electronic modules.

Next, as shown in FIG. 2D, the substrate strip 200 is singulated to separate the plurality of conductive devices 201 from each other. In particular, the singulation may be conducted along the linkage portions 208. After the singulation, the linkage portions 208 and the respective cover tape 210 on the linkage portions 208 may be removed, resulting in a plurality of separated conductive devices 201 with respective sections of the cover tape 210 attached on the top conductive pads 203 and the top surfaces of the respective dielectric bases 202. During the singulation process, a laser beam sawing process may be implemented to precisely control the positions of singulation, which avoids exposure of the conductive pillars from the dielectric bases 202.

Next, as shown in FIG. 2E, the plurality of conductive devices 201 may be loaded onto a carrier platform 230 for a subsequent deposition of a shielding layer onto the conductive devices. Before the loading process, a plurality of openings 231 may be formed in the carrier platform 230. Each opening on the carrier platform 230 may be aligned with one of the conductive devices 201 to accommodate the solder bumps 220 of the conductive device 201 within the opening 231, which improves the adhesion between the conductive devices 201 and the carrier platform 230, and reduces voids and gaps on the adhesive surface. In particular, the openings 231 may be formed within the carrier platform 230 using a laser trenching technique. Next, the plurality of conductive devices 201 are loaded onto the carrier platform 230, with solder bumps 220 of the conductive devices 201 accommodated within the respective openings 231. During the process, the bottom surfaces of the dielectric bases 202 are attached on the carrier platform 230. A front surface of the carrier platform may be adhesive to sufficiently attach the conductive devices 201 thereon. As shown in FIG. 2E, for a portion of the dielectric base 202 where the conductive patterns 206 are formed, the carrier platform 230 is attached onto the bottom surfaces of the conductive patterns 206 (region X shown in FIG. 2E), exposing the lateral surface of the conductive patterns 206. While for the other portion of the dielectric base 202, the carrier platform 230 is in direct contact with the bottom surface of the dielectric base 202 and the lateral surface of the bottom conductive pads 204 (region Y shown in FIG. 2E). In some embodiments, the carrier platform 230 may be a sputter tape such as a polymeric tape, a metallic tape, etc. In some other embodiments, the sputter tape may further include an additional adhesive layer on a top surface which is more adhesive than the other portion of the sputter tape. The additional layer provides additional adhesion and may tightly adhere to the respective surfaces of the conductive device 201 regardless of the height differences among contacting surfaces, which reduces defects such as voids or gaps.

In some other embodiments, the carrier platform 230 may include a flexible film beneath the sputter tape. The flexible film may include materials such as foam, silicone, hydrogel, etc. which can deform easily under pressure. After loading and attaching the plurality of conductive devices 201 onto the carrier platform 230, the conductive devices 201 may be pressed against the carrier platform 230 by a flat top chase or by an array of pins, for example, and the flexible film may be deformed to adjust the height of the conductive devices 201. The flexible film may alleviate potential tilting of the conductive devices 201 on the carrier platform 230 due to the non-flatness of the sputter tape resulted from the height differences of the contacting surfaces between the conductive devices 201 and the sputter tape. In this way, the shielding layer may be deposited onto the conductive devices 201 in a more uniform way.

In some embodiments, a carrier layer may first be formed on the bottom surfaces of the conductive devices to cover the bottom surfaces of the conductive patterns, the bottom surfaces of the bottom conductive pads, the bottom surfaces of the dielectric bases and the solder bumps. The carrier layer may extend to cover the lateral surfaces of the conductive patterns and the lateral surfaces of the dielectric bases. Next, a chemical mechanical polishing (CMP) process may be implemented to achieve a flat bottom surface of the carrier layer. Then the carrier layer covering the lateral surfaces of the conductive patterns and the lateral surfaces of the dielectric bases may be removed through an etching process, for example, to expose the lateral surfaces of the conductive patterns. Afterwards, openings may be formed within the carrier layer, thereby forming the carrier platform with a flat bottom surface.

Next, as shown in FIG. 2F, a shielding material is deposited towards the conductive devices 201 to form a shielding layer 240 on a lateral surface of the dielectric base 202 of each of the conductive devices 201. In particular, the shielding layer 240 is deposited on the lateral surface of the conductive patterns 206, thereby forming the electrical connection between the shielding layer 240 and the reference conductive pillar(s) 205a through the conductive patterns 206 and corresponding bottom conductive pad(s) 204. Other top conductive pad(s) 203 and bottom conductive pad(s) 204 may be covered by the cover tape 203 and the carrier platform 230, which prevents the deposition of the shielding layer 240 thereon, thereby reducing short circuit risks and prevents the electromagnetic interference from leaking out of the shielded conductive devices. In particular, the deposition of the shielding layer 240 may be conducted by a sputtering process such as an ion-beam sputtering technique, a reactive sputtering technique, high-target-utilization sputtering (HiTUS), a gas flow sputtering technique, etc., or any similar deposition processes that may form a generally conformal shielding layer.

Next, as shown in FIG. 2G, the plurality of conductive devices 201 may be unloaded from the carrier platform 230 by manipulating mechanical grippers, for example. Then the cover tape 210 together with the shielding layer 240 formed thereon may be removed from top surfaces of the plurality of conductive devices 201, exposing the top conductive pads 203, bottom conductive pads 204 and conductive patterns 206 and thereby forming the shielded conductive devices 250. In some alternative embodiments, an ejection transfer process or other similar processes may be employed to separate the conductive devices 201 from the carrier platform 230. With the above processes, the formation method of the shielded conductive devices 250 may be conducted in a mass production for lower cost and higher efficiency.

In some other embodiments, some of the conductive devices 201 do not need to be shielded since they are only used for connecting electronic devices which may not actively emit and transmit electromagnetic waves. In these embodiments, a selection process may be conducted after the singulation process in FIG. 2D to separate the conductive devices 201 into two groups, i.e., shielding conductive devices and non-shielding conductive devices. The formation process of shielding layer as illustrated in 2E to 2G may only be implemented on the shielding conductive devices.

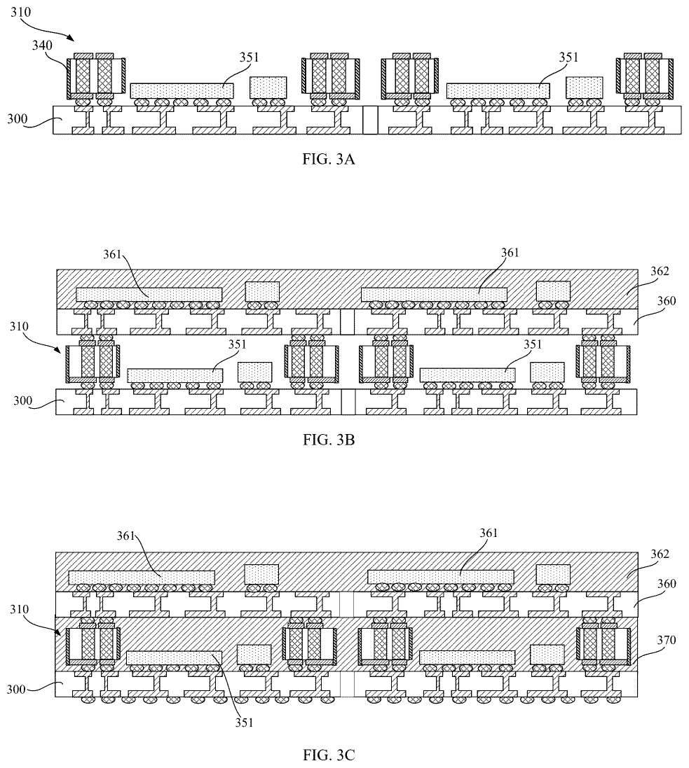

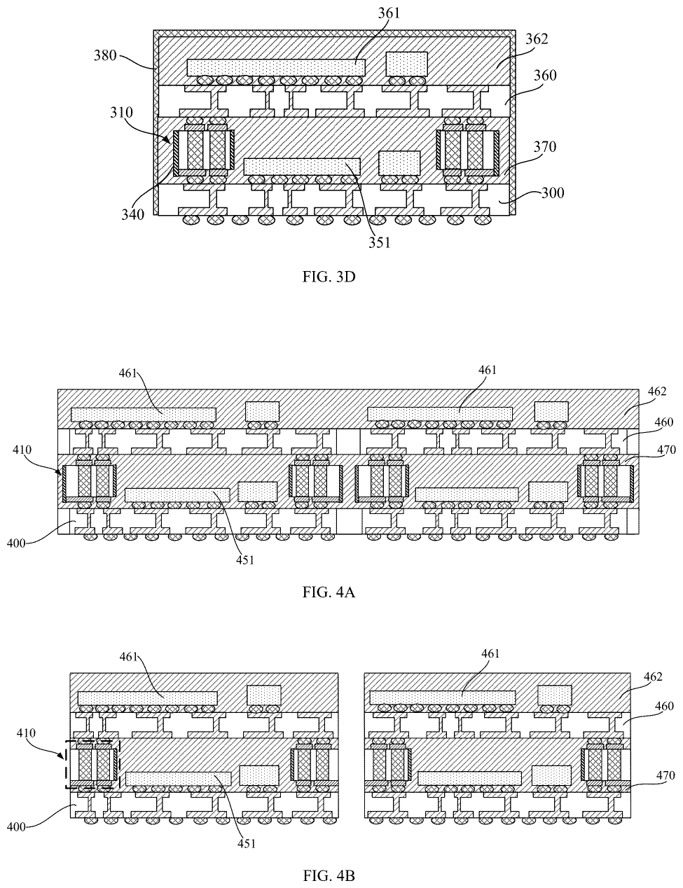

FIGS. 3A to 3D illustrate various steps of a method for forming an electronic package assembly according to a third embodiment of the present application. The electronic package assembly may be similar to the electronic package assembly shown in FIG. 1A.

As shown in FIG. 3A, a plurality of base substrates 300 may be provided in a substrate strip such that each of the base substrate 300 may serve as a platform where electronic components can be formed. In this embodiment, the substrate strip may also include a plurality of linkage portions 308, each of which is positioned between two adjacent base substrates 300, thus connecting the plurality of base substrates 300 as the substrate strip. In this embodiment, each of the base substrates 300 may have the same or similar structures. For simplicity, the following steps of forming the electronic package assembly may be illustrated with reference to one of the base substrates 300. It can be appreciated that a plurality of electronic package assemblies may be formed using the same processing on the plurality of base substrates 300. At least one electronic component 351 and at least one shielded conductive device 310 are mounted on a front surface of the base substrate 300.

Next, as shown in FIG. 3B, an upper substrate 360 may be mounted on top surface(s) of the at least one shielded conductive device 310. Next, at least one upper electronic component 361 is mounted on the upper substrate 360 and electrically connected with the at least one shielded conductive device 310. The upper electronic component 361 includes a wireless communication device. In some embodiments, at least one additional upper electronic component may also be mounted on the upper substrate 360. Next, an upper molding layer 362 is formed on the front surface of the upper substrate 360 to encapsulate the at least one upper electronic component 361.

Next, as shown in FIG. 3C, a molding layer 370 is formed between the front surface of the base substrate 300 and a bottom surface of the upper substrate 360 to encapsulate the at least one electronic component 351 and the at least one shielded conductive device 310. In some embodiments, the molding layer 370 may be formed using a film assisted molding process. Next, additional solder bumps may be formed on a back surface of the base substrate 300 for mounting of the electronic package assembly onto external electronic modules.

Next, as shown in FIG. 3D, the substrate strip may be singulated with structures thereon to form separated electronic package assemblies. Then an additional shielding layer 380 may be formed on lateral surfaces of the base substrate 300, the molding layer 370, the upper substrate 360, the upper molding layer 362 and a top surface of the upper molding layer 362.

The details of the structures of the base substrate 300, the upper substrate 360, the electronic component 351, the shielded conductive device 310 and the upper electronic component 361 may be similar to those illustrated in the electronic package assembly shown in FIG. 1A, which will not be elaborated in detail here for simplicity.

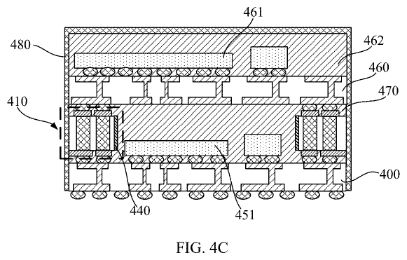

FIGS. 4A to 4C illustrate a portion of various steps of a method for forming an electronic package assembly according to a fourth embodiment of the present application.

As shown in FIG. 4A, a plurality of base substrates 400 may be provided in a substrate strip. In this embodiment, the substrate strip may also include a plurality of linkage portions similar as saw streets, each of which is positioned between two adjacent base substrates 400, thus connecting the plurality of base substrates 400 as the substrate strip. For simplicity, the following steps of forming the electronic package assembly may be illustrated with reference to one of the base substrates 400. At least one electronic component 451 and at least one shielded conductive device 410 are mounted on a front surface of the base substrate 400. The shielded conductive device 410 includes a dielectric base, a plurality of conductive pillars (including reference conductive pillar(s) and signal conductive pillar(s)), top conductive pads, bottom conductive pads, a shielding layer formed on the lateral surface of the dielectric base, and conductive patterns electrically connecting the shielding layer and at least one reference conductive pillar.

Next, an upper substrate 460 may be mounted on top surface(s) of the at least one shielded conductive device 410. Next, at least one upper electronic component 461 is mounted on the upper substrate 460 and electrically connected with the at least one shielded conductive device 410. The upper electronic component 461 includes a wireless communication device. In some embodiments, at least one additional upper electronic component may also be mounted on the upper substrate 460. Next, an upper molding layer 462 is formed on the front surface of the upper substrate 460 to encapsulate the at least one upper electronic component 461. Next, a molding layer 470 is formed between the front surface of the base substrate 400 and a bottom surface of the upper substrate 460 to encapsulate the at least one electronic component 451 and the at least one shielded conductive device 410. Next, additional solder bumps may be formed on a back surface of the base substrate 400 for mounting of the electronic package assembly onto external electronic modules.

The details of the formation process of the base substrate 400, the upper substrate 460, the electronic component 451, the shielded conductive device 410 and the upper electronic component 461 may be similar to those illustrated in the electronic package assembly shown in FIGS. 3A to 3D, which will not be elaborated in detail here for simplicity.

Next, as shown in FIG. 4B, the substrate strip may be singulated with structures thereon to form separated electronic package assemblies by removing the linkage portions and structures thereon. During the singulation process, a portion of the shielded conductive device 410 adjacent to the linkage portions (i.e., saw streets) may be removed together with the linkage portions, thereby exposing a lateral surface of the dielectric base and the conductive patterns of the shielded conductive device 410.

Next, as shown in FIG. 4C, an additional shielding layer 480 may be formed on lateral surfaces of the base substrate 400, the molding layer 470, the upper substrate 460, the upper molding layer 462 and a top surface of the upper molding layer 462, thereby forming the electronic package assembly. In particular, the additional shielding layer 480 may also be formed on lateral surfaces of the dielectric base and the conductive patterns of the shielded conductive device 410. Therefore, the additional shielding layer 480 is electrically connected to the at least one reference conductive pillar through the conductive patterns. In this way, the additional shielding layer 480 may serve as an electromagnetic interference (EMI) shielding layer for both of the whole electronic package assembly and the shielded conductive device 410, and the additional shielding layer 480 may be coupled to a reference voltage (such as being grounded) by being connected to the at least one reference conductive pillar, which saves individual connection structures for grounding.

While the exemplary method for forming a shielded conductive device of the present application is described in conjunction with corresponding figures, it will be understood by those skilled in the art that modifications and adaptations to the method for forming a shielded conductive device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A shielded conductive device, comprising:
a dielectric base having a top surface and a bottom surface, and a lateral surface extending between the top surface and the bottom surface;
top conductive pads and bottom conductive pads formed on the top surface and the bottom surface of the dielectric base, respectively;
a plurality of conductive pillars extending through the dielectric base and electrically connecting the top conductive pads with the bottom conductive pads, wherein the plurality of conductive pillars comprise at least one reference conductive pillar configured for connection with a reference voltage and at least one signal conductive pillar configured for signal transmission; and
a shielding layer formed on the lateral surface of the dielectric base to reduce electromagnetic interferences propagating into an external space of the shielded conductive device, and wherein the shielding layer is electrically connected to the at least one reference conductive pillar through at least a corresponding top conductive pad or bottom conductive pad.

2. The shielded conductive device of claim 1, wherein the shielding layer is formed on the lateral surface of the dielectric base and does not extend to either of the top surface and the bottom surface of the dielectric base.

3. The shielded conductive device of claim 1, further comprising:
conductive patterns formed on the top surface or the bottom surface of the dielectric base and between the shielding layer and at least one reference conductive pillar to electrically connecting the shielding layer and at least one reference conductive pillar.

4. The shielded conductive device of claim 1, further comprising:
solder bumps formed on at least a portion of the top and bottom conductive pads.

5. The shielded conductive device of claim 1, wherein the shielding layer is formed using the following steps:
attaching a cover tape onto the top surface of the dielectric base;
loading the dielectric base on a carrier platform with the bottom surface of the dielectric base attached on the carrier platform;
depositing towards the dielectric base a shielding material to form the shielding layer on the lateral surface of the dielectric base; and
removing the cover tape and the carrier platform from the dielectric base.

6. A method for forming shielded conductive devices, the method comprising:
providing a substrate strip comprising a plurality of conductive devices, wherein each of the plurality of conductive devices comprises:
a dielectric base having a top surface and a bottom surface and a lateral surface extending between the top surface and the bottom surface;
top conductive pads and bottom conductive pads formed on the top surface and the bottom surface of the dielectric base, respectively; and
a plurality of conductive pillars extending through the dielectric base and electrically connecting the top conductive pads with the bottom conductive pads, wherein the plurality of conductive pillars comprise at least one reference conductive pillar configured for connection with a reference voltage and at least one signal conductive pillar configured for signal transmission;
attaching a cover tape onto a top surface of the substrate strip;
singulating the substrate strip to separate the plurality of conductive devices from each other;
loading the plurality of conductive devices onto a carrier platform with the bottom surfaces of the dielectric bases of the conductive devices attached on the carrier platform;
depositing towards the conductive devices a shielding material to form a shielding layer on a lateral surface of the dielectric base of each of the conductive devices, wherein the shielding layer is electrically connected to the at least one reference conductive pillar through at least a corresponding top conductive pad or bottom conductive pad; and
removing the cover tape and the carrier platform from the plurality of conductive devices.

7. The method of claim 6, wherein the method further comprises:
forming solder bumps onto the bottom conductive pads of the conductive devices before singulating the substrate strip; and
loading the plurality of conductive devices onto a carrier platform further comprises:
forming openings in the carrier platform; and
loading the plurality of conductive devices onto a carrier platform to align each opening with one of the conductive devices to accommodate the solder bumps of the conductive device within the opening.

8. The method of claim 6, wherein the method further comprises:
forming solder bumps onto the bottom conductive pads of the conductive devices before singulating the substrate strip; and
loading the plurality of conductive devices onto a carrier platform further comprises:
forming a carrier layer on bottom surfaces of the conductive devices and the solder bumps;
applying a flattening process to flatten a bottom surface of the carrier layer; and
forming openings in the carrier layer to align each opening with one of the conductive devices to accommodate the solder bumps of the conductive device within the opening.

9. The method of claim 6, wherein the carrier platform comprises a sputter tape.

10. The method of claim 6, wherein the carrier platform comprises a sputter tape and a flexible film beneath the sputter tape.

11. The method of claim 10, wherein loading the plurality of conductive devices onto a carrier platform further comprises:
pressing the conductive devices against the carrier platform to adjust heights of the conductive devices via deformation of the flexible film.

12. An electronic package assembly, comprising:
a base substrate and an upper substrate;
at least one electronic component mounted on a front surface of the base substrate;
at least one shielded conductive device mounted on the front surface of the base substrate and between the base substrate and the upper substrate, and for electrically connecting the base substrate and the upper substrate, wherein the shielded conductive device comprises:
a dielectric base having a top surface and a bottom surface and a lateral surface extending between the top surface and the bottom surface;
top conductive pads and bottom conductive pads formed on the top surface and the bottom surface of the dielectric base, respectively;
a plurality of conductive pillars extending through the dielectric base and electrically connecting the top conductive pads with the bottom conductive pads, wherein the plurality of conductive pillars comprise at least one reference conductive pillar configured for connection with a reference voltage and at least one signal conductive pillar configured for signal transmission; and
a shielding layer formed on the lateral surface of the dielectric base to reduce electromagnetic interferences propagating into an external space of the shielded conductive device, and wherein the shielding layer is electrically connected to the at least one reference conductive pillar through at least a corresponding top conductive pad or bottom conductive pad, wherein
the bottom conductive pads of the at least one shielded conductive device are attached on the front surface of the base substrate via solder bumps; and
at least one upper electronic component mounted on the upper substrate and electrically connected with the at least one shielded conductive device, wherein the upper electronic component comprises a wireless communication device.

13. The electronic package assembly of claim 12, wherein the electronic component comprises an ultra-wide bandwidth communication integrated circuit chip.

14. The electronic package assembly of claim 12, further comprising:
a molding layer between the front surface of the base substrate and a bottom surface of the upper substrate encapsulating the at least one electronic component and the at least one shielded conductive device; and
an upper molding layer on a front surface of the upper substrate encapsulating the upper electronic component.

15. The electronic package assembly of claim 14, wherein the molding layer is formed using a film assisted molding process.

16. The electronic package assembly of claim 14, further comprising:
an additional shielding layer on lateral surfaces of the base substrate, the molding layer, the upper substrate, the upper molding layer and a top surface of the upper molding layer.

17. The electronic package assembly of claim 12, wherein the wireless communication device comprises a WiFi communication device or a Bluetooth communication device.
